(19) United States
(12) Patent Application Publication
(10) Pub. No.: US 2026/0106458 A1
(43) Pub. Date: Apr. 16, 2026

(54) REASSIGNABLE ELECTRICAL APPARATUS AND METHOD FOR CONNECTING ELECTRIC VEHICLE SUPPLY EQUIPMENT (EVSE) AND ENGINE BLOCK HEATERS WITHOUT MARKUPS ON ELECTRICITY USAGE FOR MULTIFAMILY OR MULTI-UNIT BUILDINGS

(71) Applicants: Bryce Craig Nesbitt, Berkeley, CA (US); Sven Harald Thesen, Berkeley, CA (US)

(72) Inventors: Bryce Craig Nesbitt, Berkeley, CA (US); Sven Harald Thesen, Berkeley, CA (US)

(21) Appl. No.: 19/418,745

(22) Filed: Dec. 12, 2025

Related U.S. Application Data
(63) Continuation-in-part of application No. 19/196,737, filed on May 2, 2025, now abandoned.
(60) Provisional application No. 63/641,420, filed on May 2, 2024.

(51) Int. Cl. H02J 3/007; B60L 53/30; B60L 53/62; G01R 15/18; G01R 22/06; H02J 3/001; H05K 5/02

(52) U.S. Cl. CPC H02J 3/007; B60L 53/30; B60L 53/62; G01R 15/18; G01R 22/066; H02J 3/00125; H05K 5/0221

(57) ABSTRACT

An apparatus and method are disclosed for selectively assigning shared electric loads in multi-unit buildings, such as electric vehicle supply equipment (EVSE) and engine block heaters, directly to individual tenant utility meters without sub-metering, third-party billing, or markups on electricity usage. An electrically rated enclosure defines a toollessly accessible assignment compartment that houses multiple keyed source receptacles, each permanently wired to a respective tenant meter, and multiple keyed load receptacles wired to external loads. Removable keyed assignment links interconnect selected source and load receptacles while preserving protective grounding and preventing mis-mating. Optional locks, blocking devices, and tamper-logging features provide administrative control over reassignment. Current sensors and a programmable controller enable monitoring, dynamic load management, demand-response operation, and overload prevention while ensuring that consumed energy is transparently billed to the tenant accounts associated with the selected source receptacles.

### CLAIM OF PRIORITY

This application is a continuation-in-part of U.S. application Ser. No. 19/196,737 filed May 2, 2025 titled “EV Plugbox For Electric Vehicle Charging Direct From Multifamily Apartment Cluster Meter Banks Without Service Fees”, the entire disclosure of which is hereby expressly incorporated by reference herein.

### FIELD OF TECHNOLOGY

This disclosure relates to electrical power distribution in multi-unit premises that employ cluster meter banks. In particular, it concerns reassignable connection equipment that enables external loads—such as electric-vehicle supply equipment (EVSE) and other loads such as engine block heaters—to be selectively and securely assigned to individual tenant utility meters without additional sub-metering or third-party billing, and with optional load-monitoring and control.

### BACKGROUND

Electric-vehicle (EV) adoption is accelerating, but “at-home” charging access for residents of multi-unit properties (e.g., apartments, condominiums, and mixed-use sites) lags significantly. The core barrier is not simply technical—circuits, conduits, and chargers exist—but economic and organizational. Current market structures make it hard for property owners to offer charging that is fair to non-EV residents and attractive to EV drivers who already pay their own electric utility bills.

Most existing offerings for shared parking areas are built around third-party energy resale and networked payment models. In these arrangements, a charging operator or the property's common-area account purchases electricity and then resells it through a proprietary network, typically adding per-kWh markups, session fees, or subscriptions. For a typical resident who is already the customer of record for an individual utility meter, paying a separate provider to repurchase the same commodity power can appear illogical and uneconomical. This misalignment depresses resident demand, undermines utilization, and delays broader deployment in multi-unit settings.

Using common-area power with internal “sub-metering” to allocate costs to individual residents also faces practical and regulatory hurdles. Revenue-grade meters, utility approvals, and tariff limitations can make sub-metering complex, and the administrative burden of reading, reconciling, and billing creates continuing overhead that owners and HOAs are reluctant to assume. As a result, many properties default to flat fees or generalized common-area charges that either over-or under-recover costs and invite disputes among residents.

Networked EVSE solutions introduce further frictions. Vendor lock-in, cellular connectivity requirements, recurring software fees, and payment processing costs add to the total cost of ownership while providing little value to drivers who would prefer to pay their normal utility rate. Low and variable utilization—typical in early deployment phases—magnifies these costs and extends payback periods, which deters installation. Additionally, when EVSE is tied to a single network, future changes in vendors or programs can require expensive replacements rather than simple administrative changes.

Without a straightforward attribution of kWh to a resident's existing utility account, owners face continuing disputes, manual reconciliation, or reliance on third-party resellers. Safety concerns also arise when residents resort to ad-hoc solutions (e.g., running cords from dwelling units) due to the lack of sanctioned, fairly billed access.

Finally, common-area accounts often sit on commercial tariffs with demand charges or less favorable time-of-use periods than residential meters, further decoupling the cost basis from what individual residents would otherwise pay. This creates equity issues: either EV drivers are overcharged relative to their residential rate, or non-EV residents subsidize charging through common-area budgets and HOA dues.

In short, today's options for multi-unit EV charging—third-party resale networks, tenant-specific dedicated circuits, and administrative sub-metering—each suffer from structural deficiencies: misaligned incentives, non-scaling capital requirements, regulatory and billing complexity, vendor lock-in, and ongoing operational burdens. There remains a need for approaches that allow fair, auditable attribution of charging energy to individual residents without imposing third-party resale markups, per-stall retrofits, or heavy administrative overhead.

### SUMMARY

In one aspect, a reconfigurable electrical assignment apparatus enables selective coupling of any one of multiple electric loads to any one of multiple utility service metering devices. The apparatus includes an electrically rated enclosure which may include one or more partitions that at least defines an assignment compartment which is accessible toollessly. A plurality of keyed source receptacles are mounted to and insulated from the partition, each permanently wired to a respective utility service metering device. A plurality of keyed load receptacles are also mounted to the partition and are electrically isolated from the source receptacles. Removable, keyed assignment links provide a manual, tool-free interconnection between a chosen source receptacle and a chosen load receptacle. Each assignment link has a first keyed connector mateable only with a source receptacle and a second keyed connector mateable only with a load receptacle; when an assignment link is installed within the assignment compartment, the corresponding utility service metering device is electrically coupled to the selected electric load.

In another aspect, a method is provided for selectively assigning any one of multiple electric loads to any one of multiple utility service metering devices. The method includes unlocking and opening a cover to access the assignment compartment of an electrically rated enclosure; disengaging an assignment link from a first receptacle; engaging the assignment link's source connector with a second source receptacle that is electrically connected to a desired utility service metering device; and engaging the assignment link's load connector with a selected load receptacle that is electrically connectable to an electric load. The cover is then closed and locked. Current drawn through the second source receptacle is automatically sensed, and when aggregate current exceeds a threshold, a controller is signaled to reduce or pause the electric load.

### BRIEF DESCRIPTION OF THE FIGURES

The drawings constitute a part of this specification and include exemplary embodiments to the instant invention, which may be embodied in various forms. It is to be understood that in some instances various aspects of the instant embodiments may be shown exaggerated or enlarged to facilitate an understanding of the instant embodiment.

FIG. 1 is a schematic diagram which illustrates a reconfigurable electrical assignment apparatus, according to one or more embodiments.

FIG. 2A shows the reconfigurable electrical assignment apparatus of FIG. 1 with two deadfront regions, overcurrent protection and a load management controller.

FIG. 2B shows an alternative arrangement in which a deadfront region covers a different subset of components while preserving toolless access to the assignment region.

FIG. 2C shows an embodiment that employs touch-safe keyed connectors in the assignment region instead of a deadfront.

FIG. 2D shows an embodiment of the reconfigurable electrical assignment apparatus with multiple deadfront regions and an arrangement that allows use of flexible cabling for the assignment region compared to the load conductors.

FIG. 3 is a perspective view of the reconfigurable electrical assignment apparatus integrated with a multi-unit building cluster meter, according to one or more embodiments. A single deadfront area is illustrated.

FIG. 4 is a view of the reconfigurable electrical assignment apparatus with a lockable cover opened and a deadfront compartment shut.

FIG. 5 is a view of the reconfigurable electrical assignment apparatus with the lockable cover closed, showing an optional clear window into the assignment area.

FIG. 6 is a simplified circuit diagram showing typical current art for EV charging in a multi-unit complex.

FIG. 7 is a simplified circuit diagram showing the reconfigurable electrical assignment apparatus as used in a multi-unit complex.

FIG. 8 is a simplified circuit showing the reconfigurable electrical assignment apparatus as used in a multi-unit complex, incorporating from the art dynamic load management to prevent overload of the building main.

FIG. 9 is a simplified circuit showing the reconfigurable electrical assignment apparatus as used in a multi-unit complex, incorporating dynamic load management to prevent overload of the building main, and dynamic load management at the unit level to prevent overload of the unit.

FIG. 10 shows the reconfigurable electrical assignment apparatus of FIG. 9 employing wireless current sensing breakers.

### DETAILED DESCRIPTION

The embodiments described herein provide apparatus and methods for selectively assigning any of multiple electric loads (e.g., EVSE) to any of multiple tenant utility service metering devices in a multi-meter property. While examples focus on EV charging, the same structures apply to other shared/outdoor loads (e.g., engine block heaters, hot tubs).

### System Overview

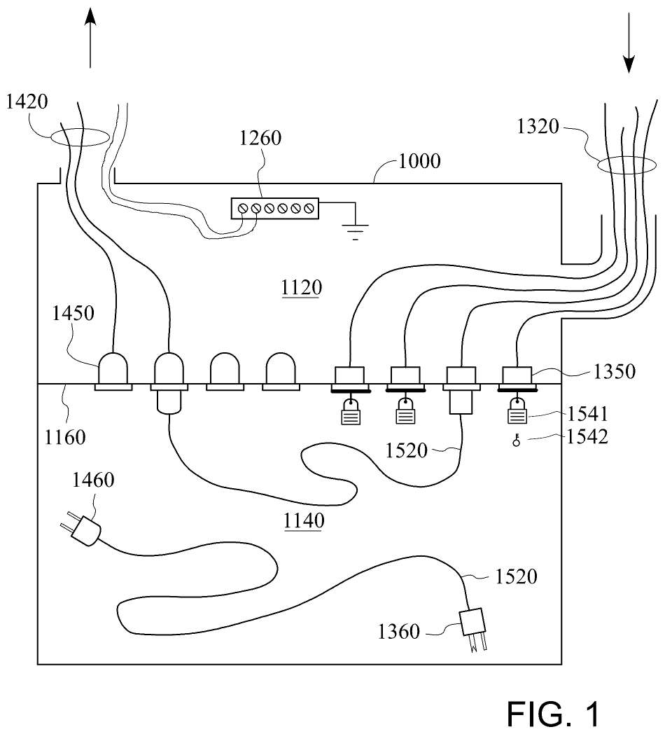

Referring to FIG. 1, in one embodiment, a reconfigurable electrical assignment apparatus is housed in an electrically rated enclosure 1000 partitioned by a panel 1160 into a deadfront region 1120 accessibly by qualified persons only (i.e., secured by tool-required fasteners 1212), and an assignment region 1140 that authorized personnel can access without tools to perform reassignments.

A plurality of source conductors 1320 from respective tenant utility metering devices (e.g., a cluster meter) may terminate at keyed source receptacles 1350 mounted to and insulated from the panel 1160. A plurality of load conductors 1420 leading to external loads (e.g., EVSE pedestals) terminated at keyed load receptacles 1450 also mounted to the panel 1160 and electrically isolated from the keyed source receptacles 1350. Mechanical keying and dissimilar gendering ensure a source plug (e.g. source plug 1360) cannot mate with a load receptacle (e.g. load receptacle 1450) and a load plug (e.g. load plug 1460) cannot mate with a source receptacle (e.g. source receptacle 1350). A grounding bar 1260 is provided within the enclosure 1000 to connect all ground wires as required by applicable standards. Protective grounding conductors of the loads terminate permanently in the grounding bar 1260 and are not switched by the assignment link; thus, protective grounding is maintained regardless of assignment state.

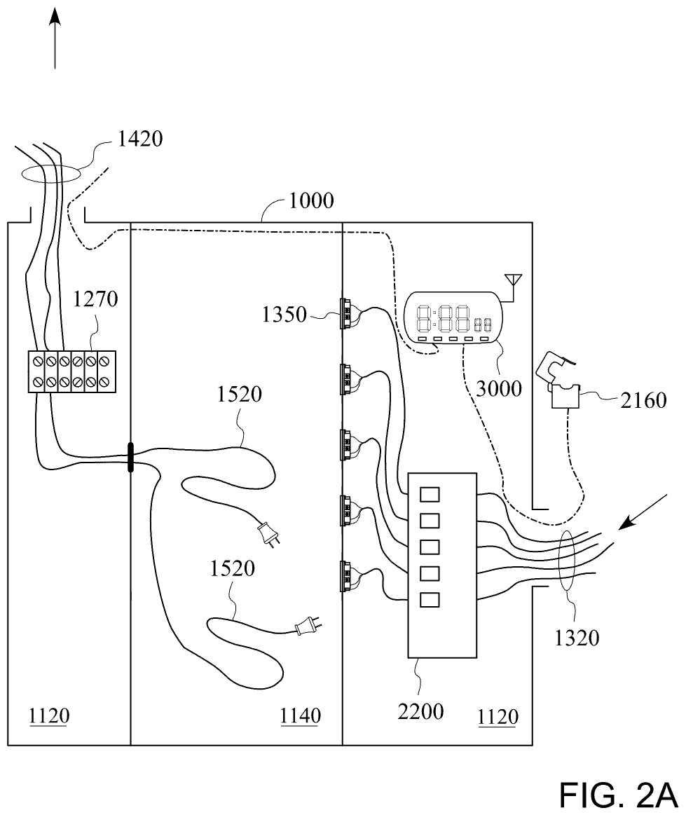

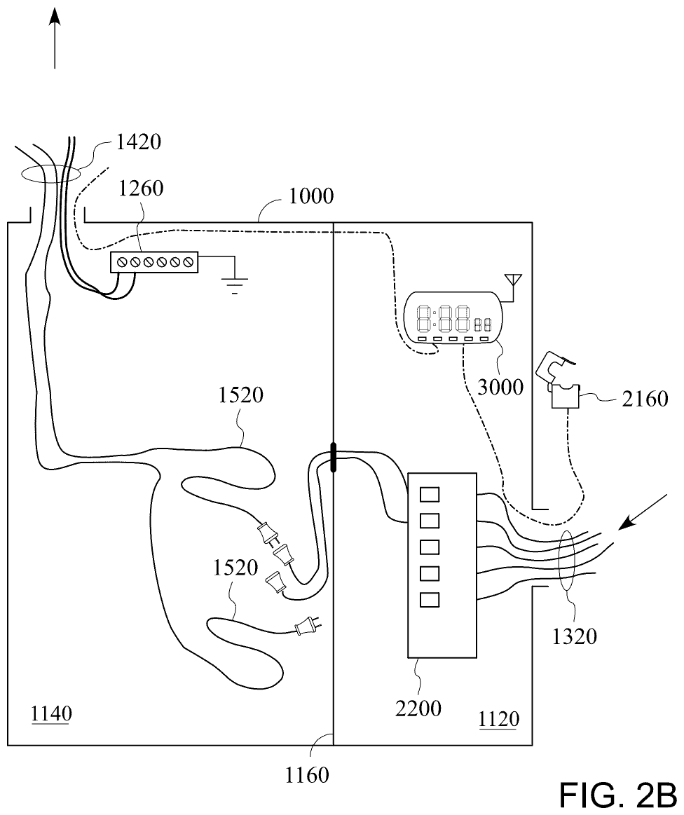

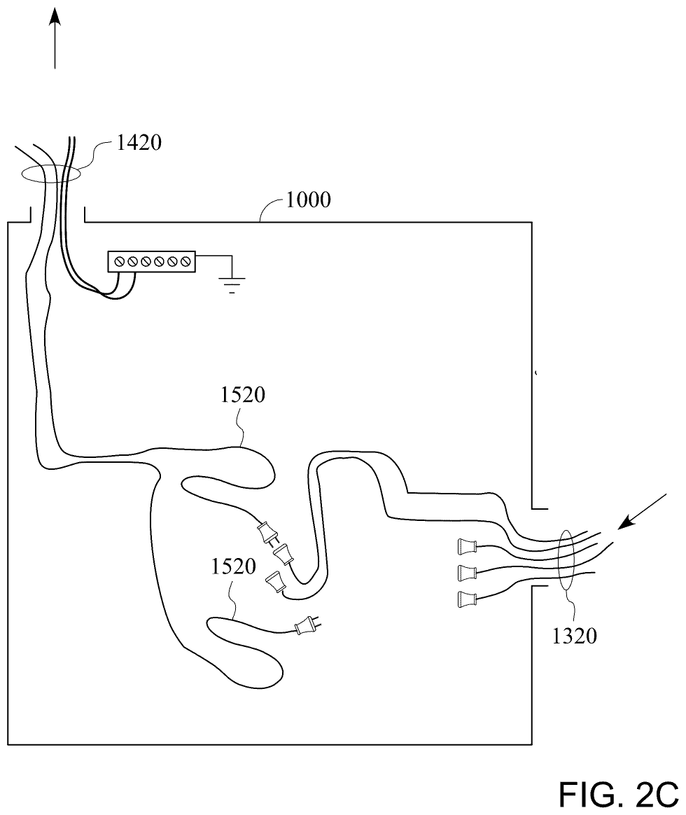

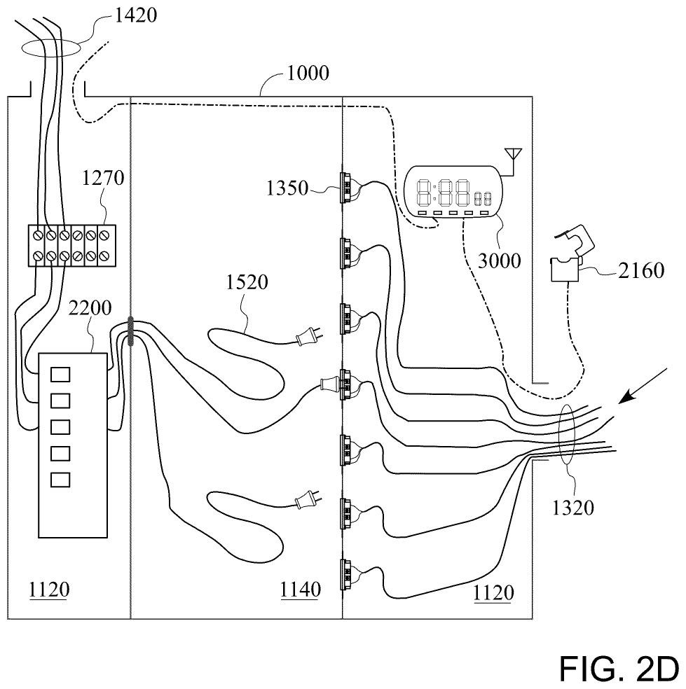

Alternately, as shown in FIG. 2A, the enclosure 1000 may comprise multiple deadfront regions 1120, including a deadfront region that covers an electrical transition block 1270. The electrical transition block 1270 may allow the flexible cables 1520 to be a different type, gauge, or rating from the load conductors 1420. In some embodiments, the enclosure defines multiple deadfront regions, or one or more deadfront regions 1120 located differently from FIG. 2A. The partition 1160 may be positioned to segregate energized terminations and serviceable devices from the assignment region while preserving toolless access for reassignments. In other embodiments, a dedicated deadfront region 1120 may be omitted such as in FIG. 2C. Instead, the apparatus may employ touch-safe, keyed bulkhead connectors for the source receptacles 1350 and load receptacles 1450 that prevent finger access to live parts when energized, thereby providing the safety function of a deadfront while maintaining toolless access within the assignment region 1140. The remaining elements (e.g., overcurrent devices 2200, current transformers (CTs) 2100/2160, controller 3000) can be arranged as shown in FIG. 2A.

Removable assignment links 1520 selectively interconnect any chosen source receptacle 1350 to any chosen load conductor 1420. Installing an assignment link in the assignment region 1140, the corresponding tenant-metered circuit is electrically coupled to the selected load.

### Overcurrent Protection and Load Management

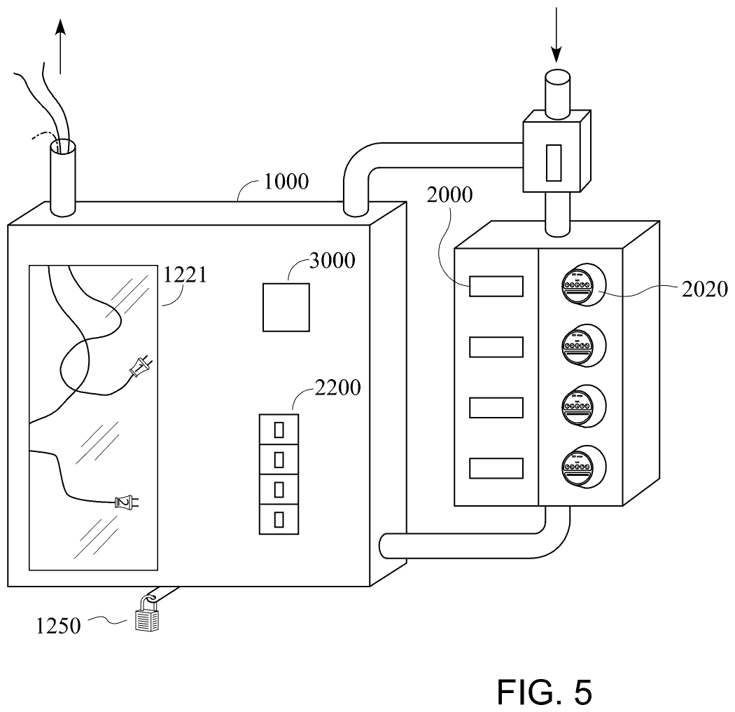

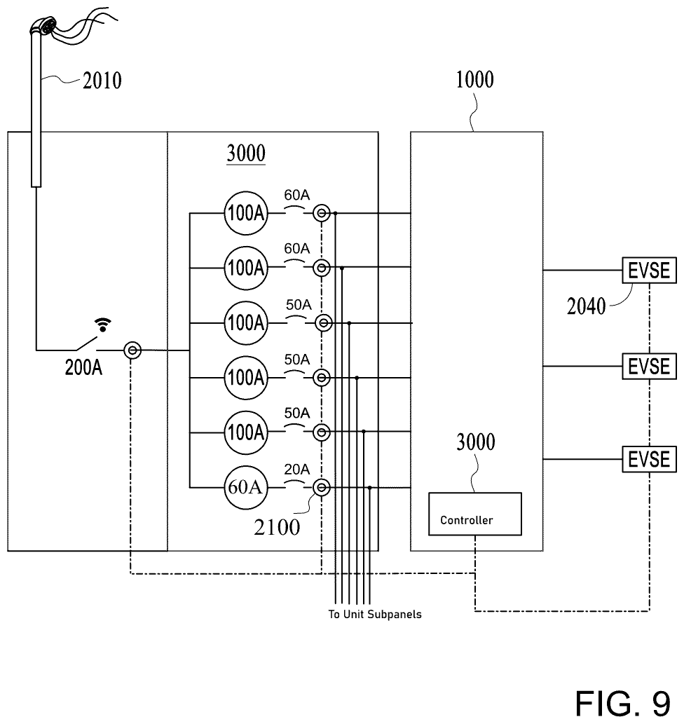

Referring to FIGS. 2A-D, 3, 5, 8 and 9, the reconfigurable electrical assignment apparatus comprises overcurrent and/or residual-current protective devices 2200 which are connected in series with the source receptacles 1350. As shown in FIG. 5, in one embodiment, the overcurrent protective devices 2200 may be exposed on the outside of a locked cover, allowing the respective meter owner to reset a tripped breaker without intervention of building management. Current sensors—e.g., CTs 2100 on tenant source conductors 1320 (as shown in FIG. 9) and a building-main CT 2160—provide measurements to a programmable load current controller 3000. The programmable load current controller 3000 may provide a display of power usage or current usage (e.g. 5.6 kW, 179 A).

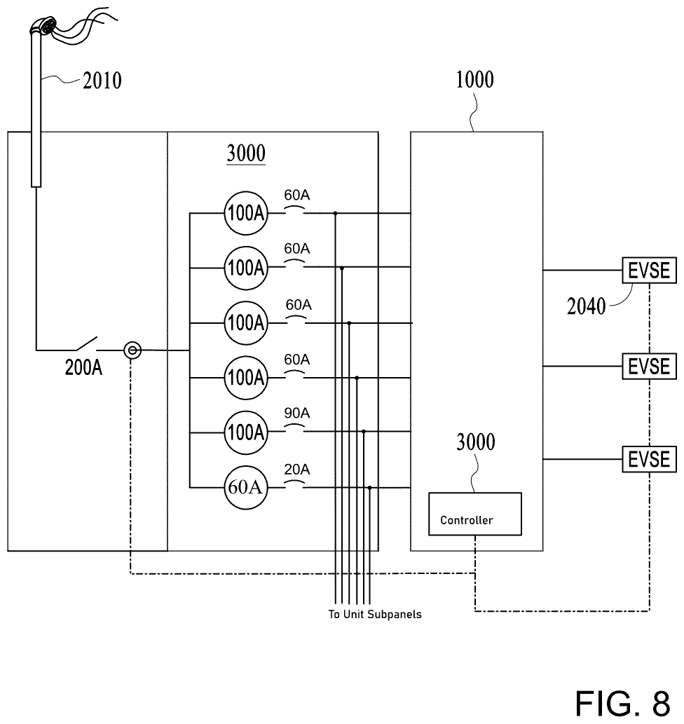

Based on aggregate and/or per-circuit current thresholds, controller 3000 may modulate one or more electric loads or suspend operations (e.g., dynamic EVSE current derating, pause/resume, demand-response curtailment). Communication may be wired or wireless, using any supported protocol (e.. g, standards-based open charge point protocol (OCPP), proprietary APIs, MODBUS) without limiting the apparatus to a particular vendor. FIG. 8 depicts a configuration in which controller 3000 constrains aggregate load against a property main limit using CT 2160. This may be achievable using load limiting products readily available in the market.

FIG. 9 depicts a more tailored configuration in which both building-main CT 2160 and per-tenant CTs 2100 inform optimal scheduling/curtailment—e.g., maintaining per-meter budgets while honoring a site-wide cap. Many older apartments have limited electrical capacity per unit (60 A meter sockets were common until the 1970's and there may be even starker constraints with old buildings). For this reason the addition of per-unit current sensing allows greater utilization of each unit meter circuit. For example a resident may use a cooking device which uses a large fraction of the available circuit capacity while warming up, but is only a temporary load. In this case the controller may identify a meter heading to an overload condition and modulate all loads down until the overloaded unit returns to the safe range.

In another embodiment, if the controller may be configured to identify which load matches which unit and may be able to modulate specifically that load. Reconfiguration of assignments made through the various embodiments of the inventive device may involve using load conductors in a way that diminishes the ability to determine assignments. Therefore, the ability to determine per-unit current usage and modulate that usage at per-unit and building levels without requiring more complex cabling and circuitry is a unique need that is created and fulfilled by the electrical assignment apparatus. In one embodiment, the controller may be configured to modulate an individual electrical load and detect corresponding modulations at the individual CT 2100 associated with the parking spot at which the electrical load is being directed. As reassignments to different parking spots are made and remade, the controller 3000 may retain per-unit meter level control without hindrance because the individual CTs 2100 are positioned to provide reliable, assignment-agnostic feedback.

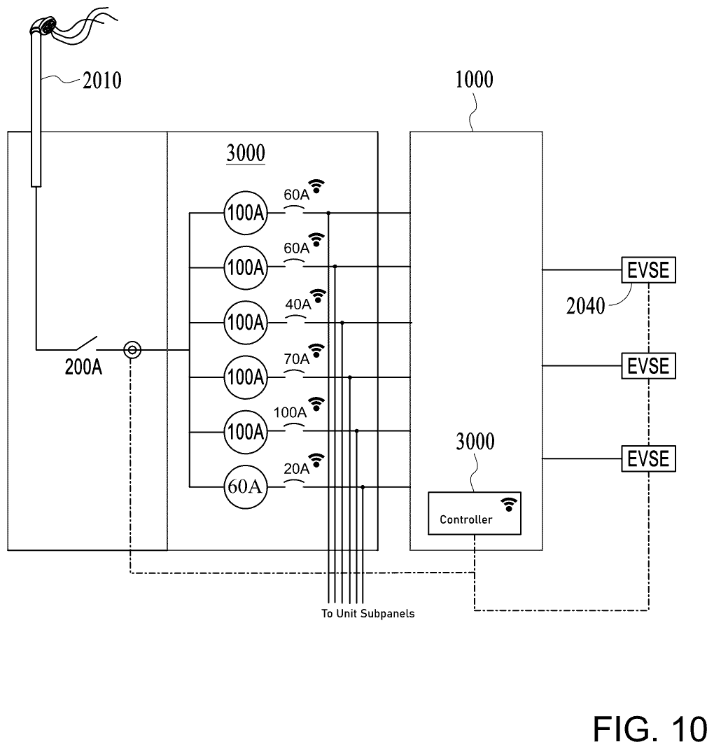

FIG. 10 shows how per-unit current monitoring may be enabled with the use of wireless enabled circuit breakers. Such circuit breakers are readily available in the market, but used uniquely to support the inventive device aims.

In another embodiment, the electrical assignment apparatus may additionally comprise an emergency shutoff switch configured to cause the controller 3000 to cut power to all electric loads. In yet another embodiment, the emergency shutoff switch may be a per-parking-spot pushbutton that may communicate to controller 3000 to disable any electric loads associated with electrical equipment associated with the parking spot. The emergency shutoff switch may be a momentary switch and may be configured to restore normal operation after a timeout or remote command without operating the switch again.

In yet another embodiment, the electrical assignment apparatus may provide means for assigned users for each parking spot to signal the load management device to deliver 0 kWh, effectively disabling the EVSE from delivering power. For example, transmitting the signal may involve using a pushbutton provided at the parking location or transmitting a wireless signal to a transceiver configured to receive the RF signal and shut off power. In the embodiment shown in FIG. 10, the wireless enabled circuit breakers may be communicatively coupled to an application executable through a user's data processing device (e.g. PC, tablet, smartphone) which may provide a user with the ability to disable power at their individual parking spot.

### Integration at Multi-meter Properties

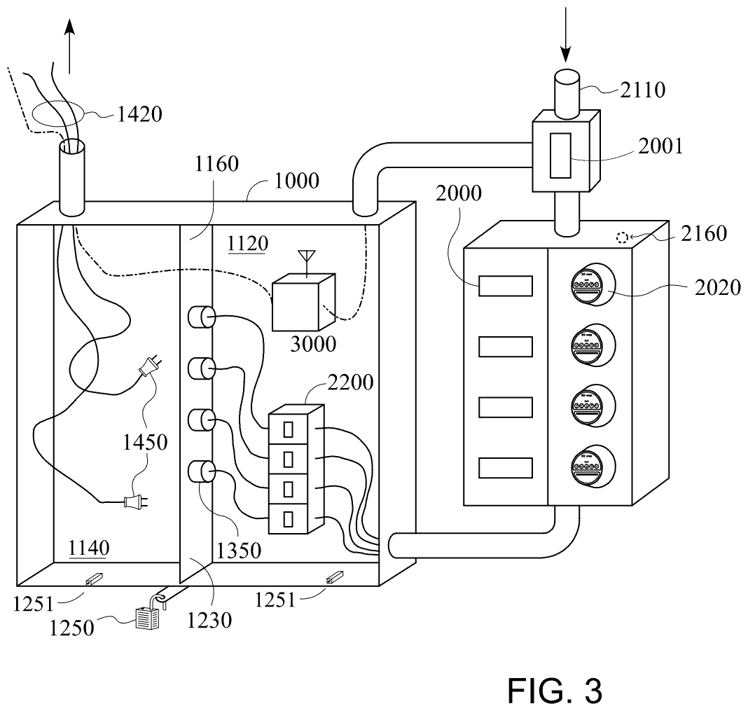

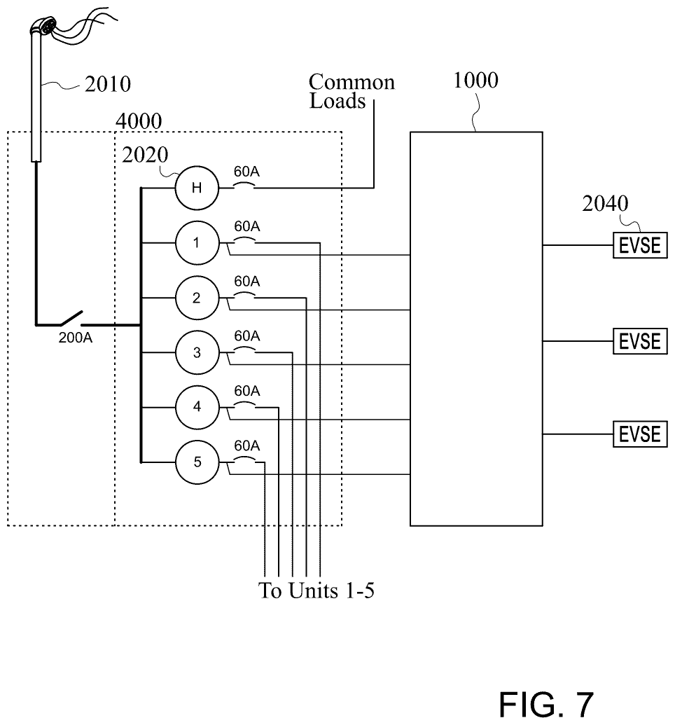

Referring to FIGS. 3 and 7, the reconfigurable electrical assignment apparatus may be mounted proximally to or integrated with an existing cluster meter 4000, receiving power from individual meters 2020. In some embodiments, each source receptacle 1350 connects to its respective tenant meter at a point upstream of the tenant's subpanel shutoff/overcurrent protection 2000 (e.g., at the meter load side via a listed tap or terminal), so that energy drawn by an assigned load is measured and billed on the tenant's normal utility account with no sub-metering.

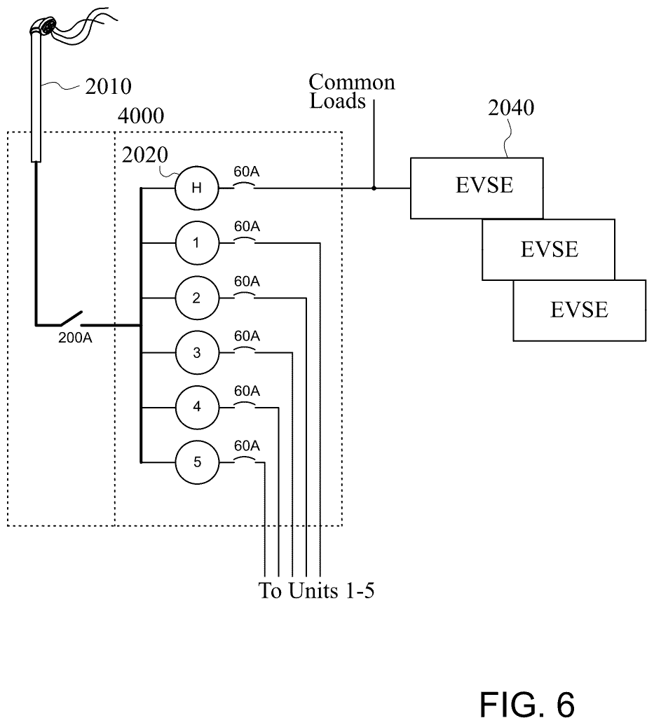

FIG. 6 schematically represents a conventional approach in which EVSE are fed from a single dwelling or common account - constraining capacity and/or forcing resale billing.

FIG. 7 shows the reconfigurable assignment approach enabling multiple EVSE 2040 to be attributed directly to different individual tenant meters, i.e., without overcurrent sensing, whereas FIG. 8 shows an extended embodiment of FIG. 7 adding site level overload prevention via load management techniques. FIG. 9 extends FIG. 7 by adding unit level overload prevention via load management techniques. FIG. 10 shows the inventive device leveraging wireless current sensing circuit breakers for limiting load on the per-unit metering devices.

### Locks and Administrative Controls

Referring to FIGS. 1, 4 and 5, a selectively deployable blocking device 1541 or similar plug-shield may be latched to a chosen source receptacle 1360 to prevent engagement by any assignment link - the blocking device 1541 may also be utilized to secure one or more load receptacles 1450. Individually lockable blocking device 1541 may have corresponding keys 1542 which may be used to prevent removal of the blocking device 1541, thus preventing unauthorized reassignment.

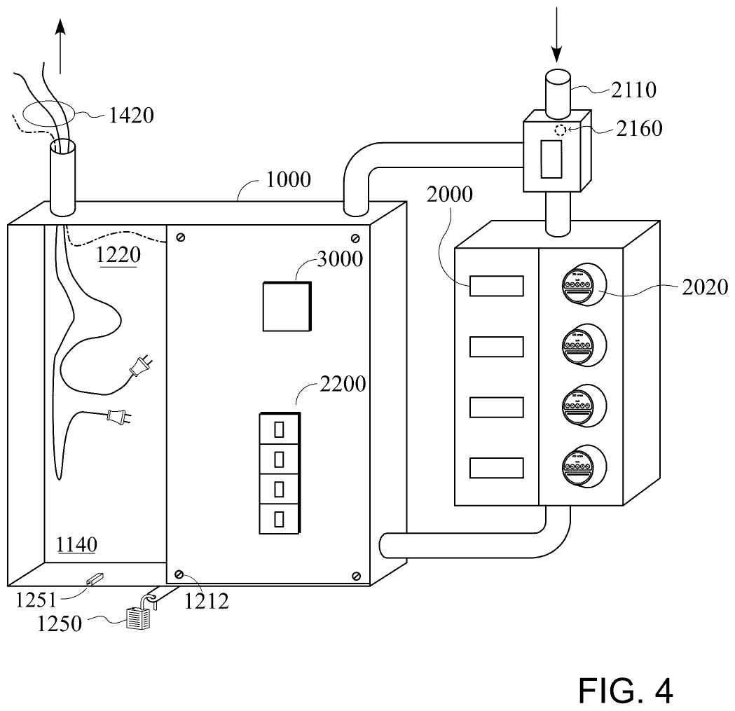

As shown in FIG. 4, the deadfront compartment cover may be secured using tool-required fasteners 1212. The assignment region 1140 may be transparently covered (e.g., with a fire-rated window) to allow visual audit of assignments and prevent casual tampering. Opening events may be logged in firmware (e.g., via tamper detection sensor 1251) with optional user identification (e.g., keyed cam-lock ID, keypad entry, or NFC credential capture) to record the authorized person performing a reassignment or opening a deadfront area. In one or more embodiments, the tamper detection sensor 1251 may be integrated into the lock 1250 or may be disposed within the deadfront area 1120 and/or the assignment region 1140. In the lock 1250 embodiment, the tamper detection sensor 1251 may log lock activation events. Lock activation events may additionally involve a keyless authentication means such as RFID (e.g. NFC). A load display of the controller 3000 may still be visible.

### Example Method of Reassignment

In an exemplary reassignment, an authorized person such as the building leasing agent disengages a lock 1250 to access the assignment region 1140; disengages an existing assignment link 1520 from either its source receptacle 1350 or load receptacle 1450; engages the link's source plug 1360 with a second source receptacle 1360 corresponding to the desired tenant meter 2020; engages the link's load plug 1460 with the chosen load receptacle 1450; recovers the assignment region 1140; and re-engages lock 1250. Current drawn through the newly selected source path is sensed automatically (e.g., via CTs 2100, 2160), and when aggregate current exceeds a threshold, controller 3000 reduces or pauses one or more loads according to configured policy.

1. A reconfigurable electrical assignment apparatus for selectively coupling any one of a plurality of electric loads to any one of a plurality of utility service metering devices, the apparatus comprising:
an electrically rated enclosure;
a partition disposed within the enclosure that divides the enclosure into at least one compartment, wherein a first compartment of the enclosure is an assignment compartment accessible toollessly;
a plurality of keyed source receptacles mounted to and insulated from the partition, each source receptacle being permanently wired to a respective utility service metering device;
a plurality of keyed load receptacles mounted to the partition and electrically isolated from the source receptacles;
a set of removable, keyed assignment links, each assignment link comprising:
a first keyed connector mateable only with one of the keyed source receptacles, and
a second keyed connector mateable only with one of the keyed load receptacles, the first keyed connector and the second keyed connector being manually engageable and disengageable toollessly;
wherein, upon installation of an assignment link in the assignment compartment, the corresponding utility service metering device is electrically coupled to a selected electric load.

2. The apparatus of claim 1, further comprising a locking cover for the assignment compartment, the cover being movable between a closed position that inhibits access to the assignment links and an open position that permits re-assignment by an authorized person without the use of tools.

3. The apparatus of claim 2, wherein the locking cover includes a transparent, fire rated window permitting visual inspection of assignment link assignments while the cover remains locked.

4. The apparatus of claim 1, wherein at least one of the electric loads comprises electric vehicle supply equipment (EVSE) located in a parking area of a multi unit premises.

5. The apparatus of claim 1, further comprising an emergency shutoff switch able to command the electrical assignment apparatus to deliver 0 kWh to all electric loads.

6. The apparatus of claim 1, wherein at least one of the electric loads comprises engine block heaters, located in a parking area of a multi-unit premises.

7. The apparatus of claim 1, wherein each of the assignment links employs dissimilar mechanical keying to prevent inadvertent interchange.

8. The apparatus of claim 1, further comprising a locking device detachably mountable to a selected source receptacle to block engagement of any assignment link with that source receptacle.

9. The apparatus of claim 1, further comprising a locking device configured to secure a selected assignment link to a selected load receptacle so that the assignment link cannot be removed without unlocking the device.

10. The apparatus of claim 2, further comprising a tamper detection sensor that generates an alarm signal when the locking cover is opened or the enclosure is breached.

11. The apparatus of claim 1, further comprising:
a plurality of current transformer sensors operatively coupled to conductors associated with one or power sources corresponding to the source receptacles; and
a programmable load current controller operatively linked to the current transformer sensors and to one or more of the electric loads, the programmable load current controller being configured to suspend or modulate operation of the electric loads to maintain aggregate current below a predefined threshold.

12. The apparatus of claim 11, wherein the current transformer sensors are arranged such that programmable load current controller can react simultaneously to per-unit and aggregate load conditions.

13. The apparatus of claim 12, wherein the controller is programmed to modulate the electrical loads and detect such modulations through the current transformer sensors, indirectly establishing one or more load-to-meter relationships.

14. The apparatus of claim 2, further comprising overcurrent and/or residual current protective devices connected in series with the source receptacles.

15. The apparatus of claim 1, wherein grounded conductors of each electric load are permanently bonded to a ground bar within the enclosure and are not part of the assignment links.

16. The apparatus of claim 1, wherein each source receptacle is connected to its respective utility service metering device at a point upstream of any unit specific sub panel.

17. The apparatus of claim 1, wherein the enclosure further comprises a deadfront compartment accessible only after removal of tool secured fasteners.

18. The apparatus of claim 17, further comprising a tamper detection sensor that generates an alarm signal when the deadfront area is opened or the enclosure is breached.

19. The apparatus of claim 1, arranged with an additional means for assigned users for each parking spot to signal the load management device to deliver 0 kWh, effectively disabling power delivery.

20. The apparatus of claim 1, with electronic means to detect which connectors have been manually attached to which receptacles, for the purpose of tamper monitoring, load limitation or control.

21. The apparatus of claim 14, wherein the control handles for any integrated overcurrent protective device are exposed outside the locked area, for manipulation by persons without access to the locked compartments.

22. The apparatus of claim 5, wherein the emergency shutoff switch is of the momentary type, and the system can be restored to normal operation based on a timer or a remote command, without physically interacting with the emergency shutoff switch.

23. A method of selectively assigning any one of a plurality of electric loads to any one of a plurality of utility service metering devices, the method comprising:
unlocking and opening an assignment compartment cover of an electrically-rated enclosure;
disengaging at least one assignment link from a first source receptacle or from a first load receptacle;
engaging a source plug of the assignment link with a second source receptacle that is electrically connected to a desired utility service metering device; and
engaging a load plug of the assignment link with a selected load receptacle that is electrically connectable to an electric load.

24. The method of claim 23, wherein the electric load comprises at least one or more of: one or more electric vehicle supply equipment (EVSE), an engine block heater, or another load and the assignment link installation permits the device to draw energy from the corresponding utility service metering device.

25. The method of claim 23, further comprising logging each occurrence of opening the assignment compartment cover together with a unique identifier of the authorized person performing the reassignment.

26. The method of claim 23, wherein the enclosure further comprises a deadfront area accessible only after removal of tool secured fasteners.
